(19) United States
(12) Patent Application Publication
(10) Pub. No.: US 2007/0210453 A1
(43) Pub. Date: Sep. 13, 2007

(54) Dummy-fill-structure placement for improved device feature location and access for integrated circuit failure analysis

(75) Inventors: Jeffrey L. Large, Dallas, TX (US); Tathagata Chatterjee, Allen, TX (US); Richard B. Irwin, Richardson, TX (US)

Correspondence Address: TEXAS INSTRUMENTS INCORPORATED, P O BOX 655474, M/S 3999, DALLAS, TX, 75265, US

(73) Assignee: Texas Instruments Inc., Dallas, TX (US)

(21) Appl. No.: 11/374,395

(22) Filed: Mar. 13, 2006

(51) Int. Cl. H01L 23/544; H01L 21/4763

(52) U.S. Cl. 257/758; 257/797; 438/622; 438/401

(57) ABSTRACT

An integrated circuit comprising interconnects located in a layer on a semiconductor substrate. The circuit also comprises dummy-fill-structures located between the interconnects in the layer. The dummy-fill-structures form a plurality of fiducials, each of the fiducials being located in a different region of the layer. Each fiducial comprises a pre-defined recognition pattern that is different from every other fiducial in adjacent regions of the layer.

### TECHNICAL FIELD

The invention is directed, in general, to semiconductive devices, and more specifically, to dummy-fill-structures in these devices and the manufacture of integrated circuits having such devices.

### BACKGROUND

Failure analysis is becoming an important component of integrated circuit fabrication. Failure analysis is often aided by the use of focused ion beam (FIB) tools to localize, characterize and repair prototype faulty devices. For example, FIB tools are used to mill through layers of a device to create cross-sections and electrical probe points to the area thought to have the fault. Even with the aid of such tools, however, the continuing push to produce smaller and faster semiconductive devices presents new challenges to conventional methods of failure analysis.

For instance, integrated circuits often employ a dense multilayered network of metal interconnections. The use of copper interconnections necessitates the use of chemical mechanical polishing (CMP) as part of the damascene processes used to fabricate copper wiring in the metal-containing layers (“metal layers”). To facilitate the production of a highly planar surface by CMP, it is desirable to introduce dummy-fill-structures between the copper wiring. Although the employment of dummy-fill-structures helps reduce dishing or erosion of polished layers, it also complicates any subsequent failure analysis of the device.

For example, thousands of dummy-fill-structures, many having the same sizes and shapes, can be present in a metal layer. Because such metal layers are not transparent to either optically or electron or ion beam-based microscopy, it is difficult to determine where to mill in order to create the cross-sections, the electrical probe points or modifications of the. circuit needed for the failure analysis of underlying areas. Additionally the dielectric is also not transparent to electron or ion beam microscopy. Milling through the wrong location can irreparably destroy the device, making it impossible to do failure analysis.

Accordingly, what is needed is an integrated circuit, and its method of manufacture, that employs dummy-fill-structures in a manner that addresses the drawbacks of prior art integrated circuits.

### SUMMARY

One embodiment is an integrated circuit. The integrated circuit comprises interconnects located in a layer on a semiconductor substrate. The circuit also comprises dummy-fill-structures located between the interconnects in the layer. The dummy-fill-structures form a plurality of fiducials, each of the fiducials being located in a different region of the layer. Each fiducial comprises a pre-defined recognition pattern that is different from every other fiducial in adjacent regions of the layer.

Another embodiment is a method of manufacturing an integrated circuit that comprises depositing an insulating layer over a semiconductor substrate and forming the above-described interconnects and dummy-fill-structures in the layer.

### DRAWINGS

FIG. 1 illustrates a cross-sectional view of a integrated circuit to which an example implementation of the invention can be applied;

FIG. 2 illustrates a plan view through a layer of an example integrated circuit of the invention;

FIG. 3 illustrates a plan view through another layer of an example integrated circuit of the invention;

FIGS. 4 to 9 illustrate cross-section views of selected steps in an example implementation of a method of fabricating an integrated circuit of the invention.

### DESCRIPTION

The present invention benefits from the recognition that the design rules for placing dummy-fill-structures in a metal layer should include rules to facilitate failure analysis. It is recognized that there are higher priority design rules for placing dummy-fill-structures in a metal layer. Dummy-fill-structures are placed to minimize the topographical variations of the metal layer when subject to CMP. Dummy-fill-structures placement also should minimize any detrimental electrical or magnetic effects in the device (e.g., cross-talk, parasitic capacitances, parasitic resistances and RC delay).

While these design rules, which allow the fabrication of a functional semiconductive device, are paramount, the inventors realized that this does not exclude the introduction of additional design rules for dummy-fill-structures to facilitate the failure analysis of the device. In particular, it is desirable to arrange the dummy-fill-structure morphology or dummy-fill-structure placement to form fiducials.

The term fiducial as used herein is defined as an arrangement of one or more dummy-fill-structures to form a unique recognition pattern. The recognition pattern refers to the morphology, arrangement or electrical properties of dummy-fill-structures that makes the one arrangement of dummy-fill-structure distinguishable from another arrangement. Unique recognition patterns can be created by changing any one or all of the dummy-fill-structure's morphology, arrangement or electrical properties.

It is emphasized that the fiducials of the present invention are unrelated to fiducials used in photolithography. Rather, the fiducials here are used to aid failure analysis processing by allowing different regions of a device surface to be uniquely identified either locally or globally. The advantages in using fiducials comprising dummy-fill-structures to aid failure analysis is unexpected because previous interest in dummy-fill-structure placement in a layer has been devoted to achieving planarity in metal layers while avoiding negative electrical and magnetic consequences.

It was discovered that a plurality of fiducials could be formed in a metal layer without violating the priority design rules for dummy-fill-structure placement. The formation of such fiducials makes it easier to uniquely identify where underlying device features are located. Providing unique recognition patterns across the metal layer, or even between different metal layers, facilitates the determination of the appropriate location to conduct failure analysis, e.g., the location to start and stop FIB milling.

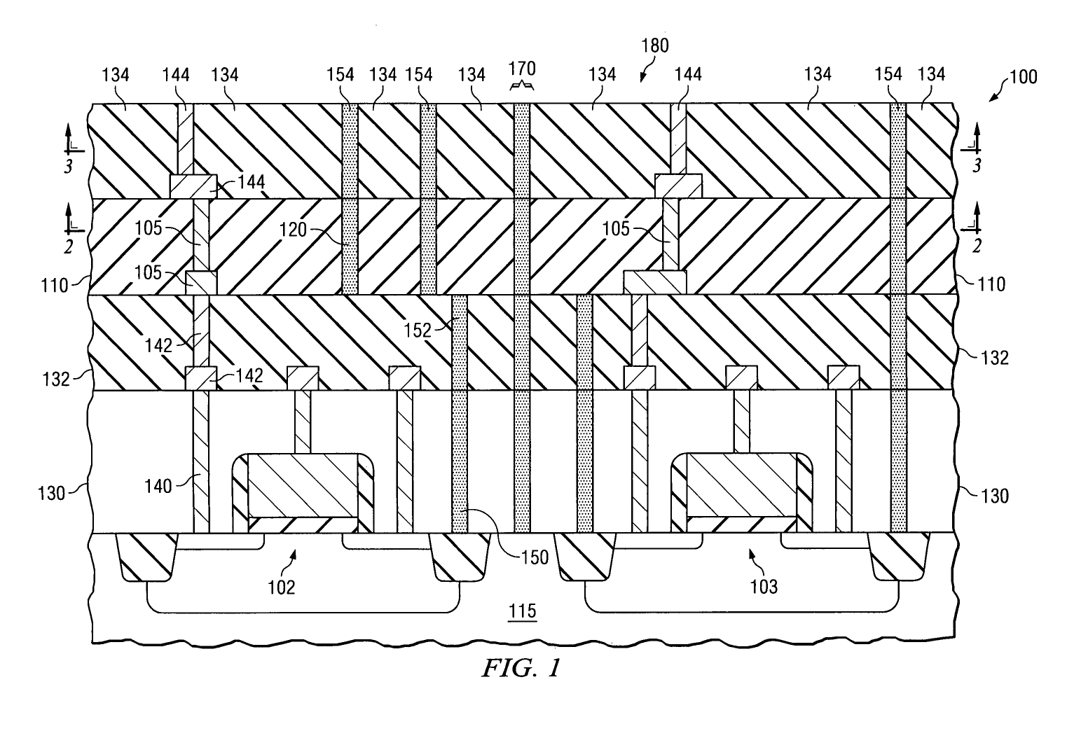

One embodiment is an integrated circuit. FIG. 1 shows a cross-sectional view of a portion of an example integrated circuit 100. The integrated circuit 100 comprises semiconductive devices 102, 103, such as active or passive devices like transistors, capacitors, or other features that are interconnected to form an operative integrated circuit 100.

As illustrated in FIG. 1, the integrated circuit 100 comprises interconnects 105 located in a layer 110 on a semiconductor substrate 115. The term interconnect as used herein refers to all types of metal wiring in a layer, including metal lines, vias, trenches, contacts or other conventional wiring. The integrated circuit 100 also comprises dummy-fill-structures 120 located between the interconnects 105 in the layer 110. The dummy-fill-structures 120 form a plurality of fiducials, each of the fiducials being located in different regions of the layer 110. Each fiducial comprises a pre-defined recognition pattern that is different from every other fiducial in adjacent regions of the layer 110.

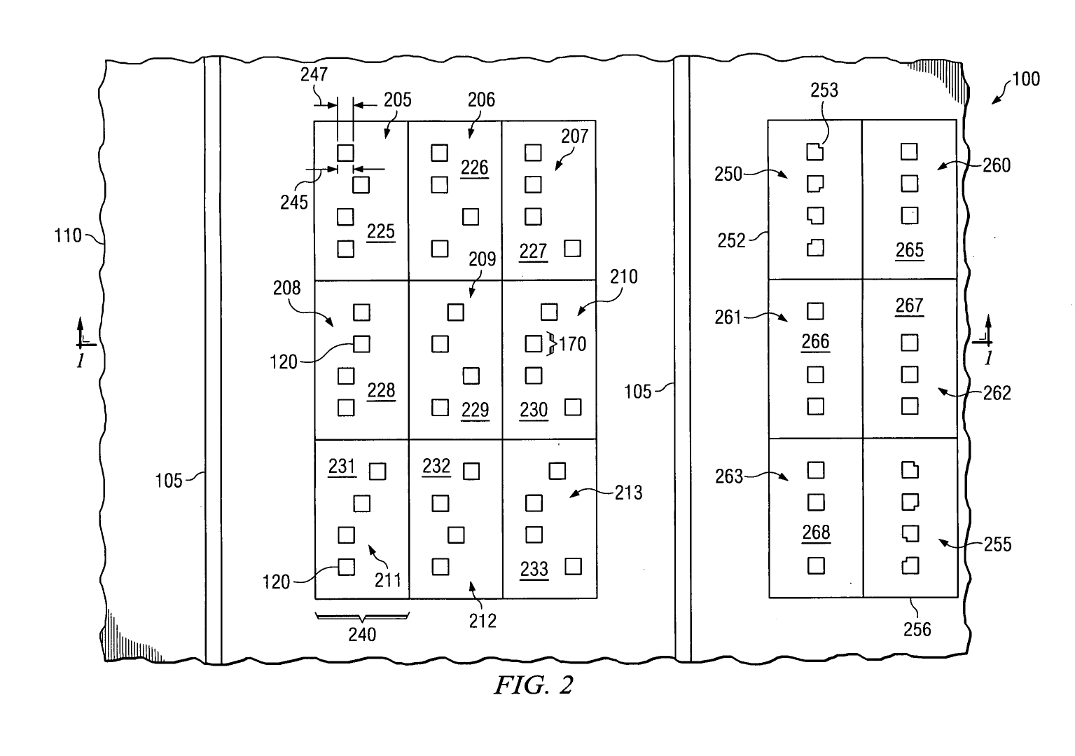

The arrangement of dummy-fill-structures in different regions to form fiducials is illustrated in FIG. 2, which shows a plan view through layer 110 along view line 2-2 (FIG. 1). FIG. 2 shows the view line 1-1 corresponding to the cross-section view presented in FIG. 1. In additional to the priority design rules for dummy-fill-structure placement, the dummy-fill-structures 120 form a plurality of fiducials 205, 206, 207, 208, 209, 210, 211, 212, 213 each of the fiducials 205, 206, 207, 208, 209, 210, 211, 212, 213 being located in different regions 225, 226, 227, 228, 229, 230, 231, 232, 233, respectively, of the layer 110. Each fiducial, e.g. fiducial 209 in region 229, comprises a pre-defined recognition pattern that is different from every other fiducial 205, 206, 207, 208, 210, 211, 212, 213 in adjacent regions 225, 226, 227, 228, 230, 231, 232, 233, of the layer 110.

The size and shape of the regions containing the fiducials is adjusted to meet the anticipated needs of failure analysis. These regions typically will correspond to the size of the hole to be milled by a FIB tool to provide a field of view for the failure analysis of underlying device features. The size of the hole to be milled, and hence the size of the region, depend on a number of factors including: the size of the underlying devices 102, 103, the type of device fault being investigated, the capabilities of the milling tool and the number of metal layers being milled.

In some cases, each region 225-233 can be a square ranging from an about 0.1 by 0.1 micron to 200 micron by 200 micron area. E.g., for the failure analysis of transistor devices have a gate length of about 180 nanometers, a region of about 7 by 7 microns might be appropriate. However, a region of about 2 by 2 microns might be more suitable for the failure analysis of transistor devices having a gate length of about 70 nanometers.

These regions 225-233 or other regions of the layer 110 need not be square, or rectangular as depicted in FIG. 2. Preferably, however, the regions have a uniform shape that facilitates laying out a plurality of regions in a grid over the layer 110 so that the recognition patterns of the fiducials can be appropriately designed, defined and stored in a database. The pre-defined recognition patterns are then used to uniquely identifying a particular region, should failure analysis of the circuit 100 be required.

As noted above, sometimes it is sufficient for the pre-defined recognition pattern of one fiducial to be different from the fiducials in adjacent regions. That is, the unique identification of fiducials is only needed for a local area of the layer. Other times, however, it is desirable for the pre-defined recognition pattern for each of the fiducials to be different from every other fiducial in the layer. For example, fiducial 209 in region 229 (FIG. 2) can be different from all other fiducials in the layer 110.

As well as identifying specific locations within a layer, it is sometimes desirable to have fiducials that uniquely identify the layer itself. For instance, in some cases it is desirable, as part of a failure analysis investigation, to remove several metal layers of the circuit by parallel polishing. Parallel polishing, however, might planarize these layers unevenly. Consequently, several different layers can be exposed simultaneously, sometimes making it difficult to determine whether the area of interest, for the layer of interest has been exposed. Additionally, uneven parallel polishing can make it impossible to isolate one exposed layer from the another in the field of view created by milling if e.g., multiple metal layers are exposed at the same time.

As further illustrated in FIG. 1, the integrated circuit 100 can comprise several additional layers 130, 132, 134 of the device 100. Each of these layers comprise interconnects 140, 142, 144 having dummy-fill-structures 150, 152, 154 located there-between. To remedy problems with identifying each layer, it is preferable for the dummy-fill-structures 150, 152, 154 in each of the additional layers 130, 132, 134 to form a plurality of additional fiducials.

Similar to layer 110, each additional fiducial, located in an additional region, comprises a pre-defined recognition pattern that is different from every other additional fiducial in adjacent regions within the additional layers 130, 132, 134. In some cases, each additional fiducial comprises a pre-defined recognition pattern that is different from every other additional fiducial in the layer. To provide inter-layer discrimination, each additional fiducial preferably is different from the fiducials in vertically adjacent regions of the additional layers. In some cases each fiducial of the layer is different from every other additional fiducial in every other additional layer.

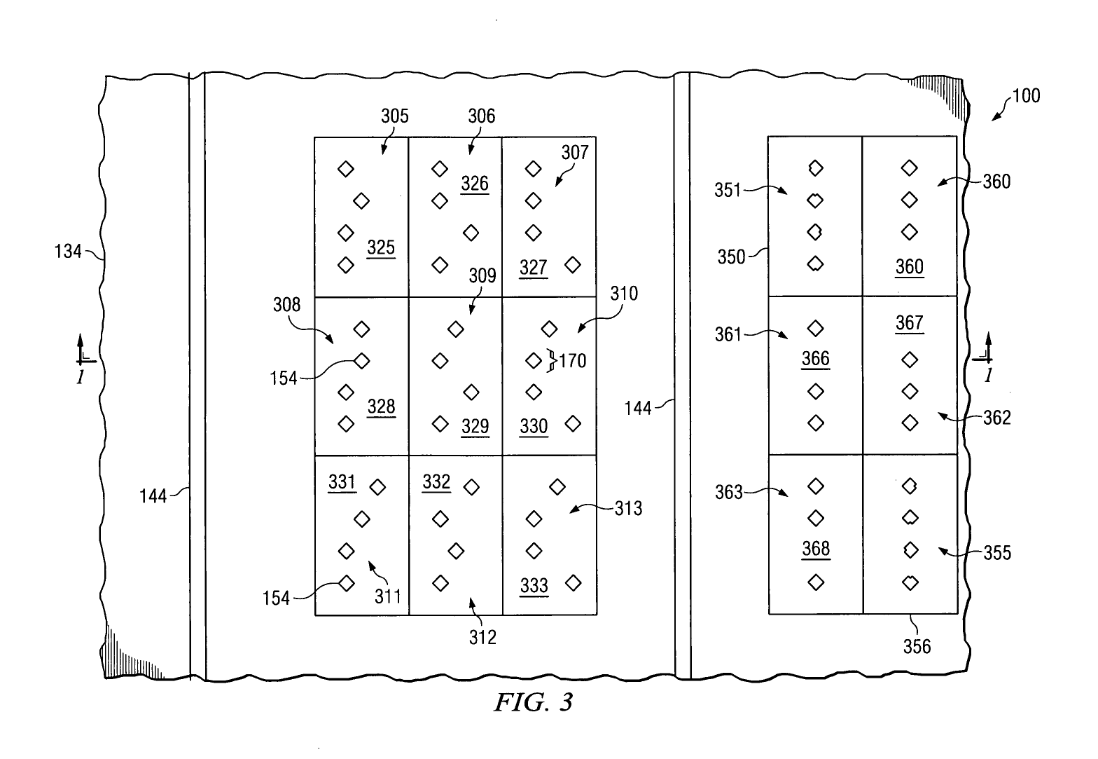

Aspects of these embodiments are illustrated in FIG. 3, which shows a plan view (through view line 3-3 in FIG. 1) through layer 134, of an example additional layer vertically adjacent to layer 110. Each additional fiducial, e.g., fiducial 309 in additional region 329, comprises a pre-defined recognition pattern that is different from every other additional fiducial 305, 306, 307, 308, 310, 311, 312, 313 in the additional adjacent regions 325, 326, 327, 328, 330, 331, 332, 333, of the layer 134. In some preferred embodiments, each fiducial 205-213 in the layer 110 is different (e.g., has a different pre-defined recognition pattern) from every other additional fiducial 305-313 in the vertically adjacent additional regions 325-333, of the adjacent additional layer 134. In still other preferred embodiments, each fiducial in each layer 110, 130, 132, 134 has a recognition pattern that is different than every other fiducial in every other layer 110, 130, 132, 134.

There are numerous ways to form the pre-defined recognition pattern of the fiducials. In some cases, the pre-defined recognition pattern comprises an ordered arrangement of one or more of the dummy-fill-structures. As illustrated in FIG. 2, for example, a pre-defined recognition pattern can include an ordered arrangement comprising an intra-layer lateral column 240 of square dummy-fill-structures 120. The recognition pattern can have other ordered arrangements of dummy-fill-structures 120 including rows, rows and columns, diagonals, crosses, alphanumeric symbols or other distinguishable arrangements.

In some embodiments, the ordered arrangement includes dummy-fill-structures that are offset from other dummy-fill-structures of the fiducial. The offset can be a-lateral offset, a vertical offset, or a combination of lateral and vertical offsets. For instance, in FIG. 2, one or more of the dummy-fill-structures 120 has a lateral offset 245 from at least one other dummy-fill-structure 120 of the fiducial 205. In some cases, the offset 245 ranges from about 10 percent to about 100 percent of a width 247 of the dummy-fill-structures. As further illustrated in FIG. 2, the offset 245 between dummy-fill-structures 120 can be configured to define unique patterns for each fiducial 205, 206, 207, 208, 209, 210, 211, 212, 213.

The pre-defined recognition pattern can be unique locally, that is, at the sub-integrated circuit chip level, or globally, that is, at a chip-wide level. Sometimes one can use the design layout for e.g., interconnections in the layer of interest as a supplemental guide to the appropriate region of the chip. In such instances, it can be sufficient for the pre-defined recognition pattern to be locally unique. Locally unique can include, uniqueness just for adjacent fiducials, or for larger areas, within the layer 110, and in some cases, locally uniqueness between adjacent layers 132, 134 (FIG. 1). In other cases, however, no such supplemental guides are available. This may be the case when one is, e.g., performing failure analysis on a 100 by 100 micron array comprising thousands of SRAM semiconductive devices. In such instances, it is desirable for the pre-defined recognition pattern to be unique globally, that is, to provide chip-wide uniqueness among all fiducials within the entire layer 110, or in some cases, between all of the layers 110, 130, 132, 134 of the circuit 100.

In other embodiments, it is the morphology of the dummy-fill-structure that is changed to form the pre-defined recognition patterns. For instance, the pre-defined recognition pattern of a fiducial can comprise one or more dummy-fill-structure whose morphology is configured to make the fiducial different than every other fiducial in adjacent regions of the layer. In some cases, every fiducial in a layer comprises one or more dummy-fill-structure having a morphology that makes the fiducial different than every other fiducial within the layer, and in some instances, different than adjacent fiducials in adjacent layers, or different than every fiducial in every layer.

Changing the morphology could include any one or more of changes to the size, shape or orientation of one or more dummy-fill-structure of a fiducial. As an example, the base shape of a square dummy-fill-structure can be modified by removing a portion of one corner or a side of one or more of the dummy-fill-structures in a fiducial. As shown in FIG. 2, e.g., for the upper-most dummy-fill-structure 120 of the fiducial 250 in region 252, a small portion of corner 253 has been removed. The dummy-fill-structures could have other base shapes including: rectangular tracks, diamonds, crosses, triangles, hexagons, or alphanumeric symbols. Any one or combination of these base shapes could be further modified by removing a portions therefrom, similar to that described above for square dummy-fill-structure 120, to define recognition patterns that are unique to each fiducial in the layer 110.

As another example, the morphology of square dummy-fill-structures 120 of one fiducial in a region can be changed by adjusting their size as compared to, e.g., the dummy-fill-structures in another fiducial or other dummy-fill-structures within the same fiducial. As shown in FIG. 2, the dummy-fill-structures 120 in fiducial 256 are about 20 percent larger than the dummy-fill-structures 120 in fiducial 250. As further illustrated for region 256, the change in size can be made in combination with other changes in morphology, such as removing the portion of corners. In other cases changes can comprise combinations of any of the changes in morphology, alignment, or electrical properties discussed herein. In some preferred embodiments, the size of dummy-fill-structures 120 is progressively decreased (e.g., by about 10 to 50 percent) between each of the layers 110, 130, 132, 134 as they get closer to the substrate 115. E.g., as shown in FIG. 1, the dummy-fill-structures 120 of layer 110 is about 10 percent smaller than the dummy-fill-structures 154 of layer 134, and the dummy-fill-structres 152 of layer 132 is about 10 percent smaller than the dummy-fill-structures 120 of layer 110.

As still another example, the morphology of the square dummy-fill-structures 120, depicted in FIG. 3 for layer 134, can be changed by adjusting its orientation. Rotating square dummy-fill-structures 120 in layer 134 by about 45 degrees relative to the dummy-fill-structures 120 in layer 110 (FIG. 2), allows one to distinguish between the dummy-fill-structures 120 that are vertically adjacent to each other in these two layers 110, 134. Of course, dummy-fill-structures in this or other layers could be rotated by amounts different than 45 degrees to distinguish between dummy-fill-structures in regions of the same or different layers.

As yet another example, altering the recognition pattern can comprise altering the electrical properties of selective ones of the dummy-fill-structures 120. By selectively electively grounding or floating dummy-fill-structures 120 within or between regions a recognition pattern can be formed. The dummy-fill-structure's electrical properties can be altered by e.g., selectively grounding one or more dummy-fill-structure 120 in a region. Consequently, when such regions are imaged via FIB or scanning electron microscopy (SEM), grounded dummy-fill-structures will provide a higher intensity signal as compared to ungrounded (or floating) dummy-fill-structures.

In some embodiments, the pre-defined recognition pattern can be formed through the absence of one or more of the dummy-fill-structures from the ordered arrangement of dummy-fill-structures. This is illustrated in FIG. 2 for fiducials 260, 261, 262, 263 in regions 265, 266, 267, 268, respectively. The absence of one dummy-fill-structure 120 from each of these fiducials 260-263 results in a unique pre-defined recognition pattern of dummy-fill-structures 120. The location of the absent dummy-fill-structures (also referred to hereinafter as the dummy-block) within the fiducial can be selected randomly or nonrandomly. A random selection of dummy blocks has the advantage of minimizing the time spent on designing the arrangement of dummy-fill-structures in a layer. This can be an advantage when there are thousands dummy-fill-structures in a single layer.

In still other embodiments, it is advantageous for the pre-defined recognition pattern of each fiducial to be substantially repeated in adjacent additional layers of the circuit 100. It is recognized that, because the layout of interconnects 144 in layer 154 is not identical to the layout of interconnects in layer 110, there are cases where the number or location of one or more of the regions 325-333, 350, 356, 365-368 will have to be altered (e.g., deleted or shifted) compared to regions 225-233, 250, 256, 265-268. However, to the extent that regions in layer 134 can have about the same location as adjacent regions in layer 110, it is desirable to repeat the pre-defined recognition pattern in the fiducials. As shown in FIG. 2 and 3, for example, each of the pre-defined recognition patterns in the fiducials 205-213, 251, 255, 260-263 of layer 110 is substantially repeated in the fiducials 305-313, 351, 355, 360-363 of layer 154.

An advantage of repeating the pre-defined recognition patterns in the fiducials from one layer to the next is that dummy-fill-structures of one layer can be located directly above or below and contact the dummy-fill-structures of the adjacent layer. Locating dummy-fill-structures directly above and below each other between layers helps prevent dummy-fill-structures from coming out the layer during CMP. As illustrated in FIGS. 1-3, the pre-defined recognition pattern in fiducial 210 in layer 110 is repeated in the additional layers 130, 132, 134. Consequently, dummy-fill-structures 120, 150, 152, 154 from several layers can contact each other and form an inter-layer vertical column 170. In some cases, the inter-layer vertical column 170 of dummy-fill-structures 120, 150, 152, 154 can run from a top surface 180 of the integrated circuit 100 to the semiconductor substrate 115 (FIG. 1). In other cases, however, the inter-layer vertical column 170 may only run between two or three adjacent layers.

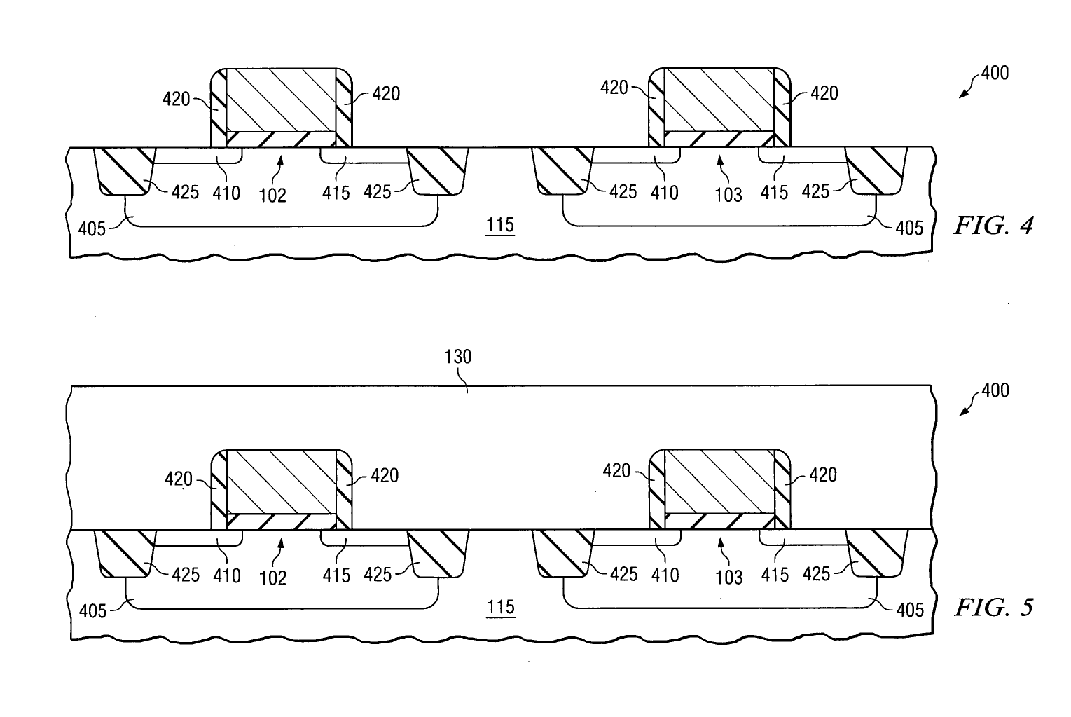

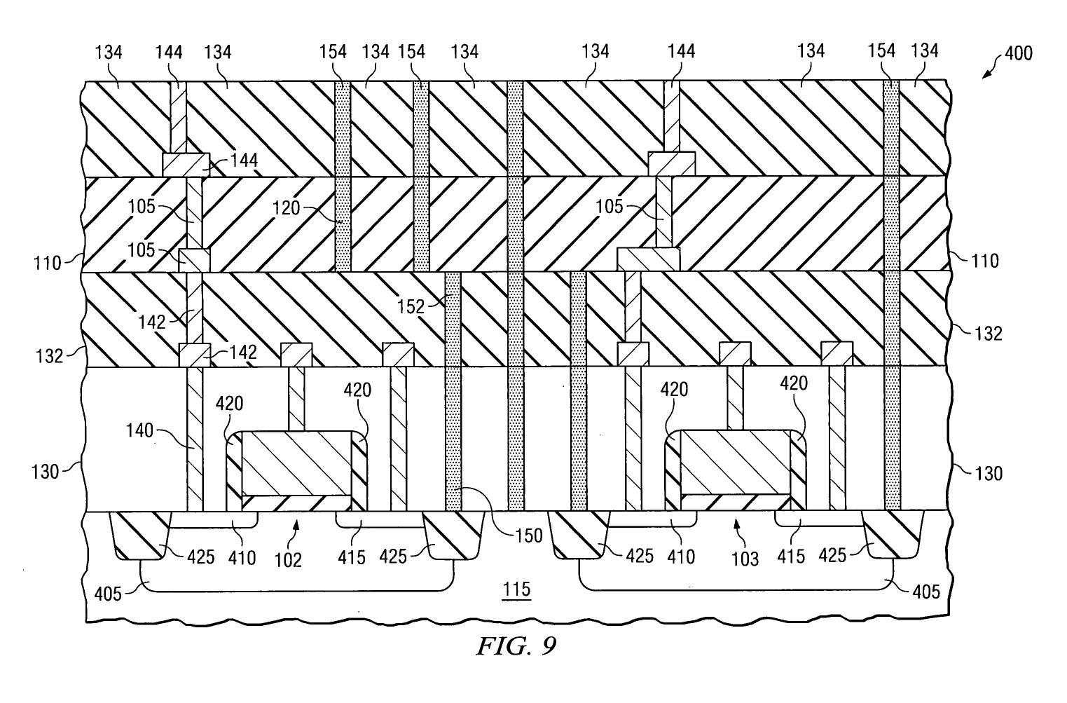

Another embodiment of the invention is a method for manufacturing an integrated circuit. Any of the embodiments of the above-described integrated circuit can be manufactured by the method. FIGS. 4 and 9 illustrate cross-section views of selected steps in an example implementation of a method of fabricating an integrated circuit 400 of the invention. The same reference numbers are used to depict analogous structures to that depicted in FIG. 1.

FIG. 4 shows the partially-completed integrated circuit 400 after forming semiconductive devices 102, 103 in or on a semiconductor substrate 115. Any number of semiconductive devices 102, 103, comprising active devices, such as a metal-oxide-silicon (MOS) transistors, or passive devices, such as capacitors, can be formed on or in the semiconductor substrate 115. Those skilled in the art would be familiar with the conventional method used to form device components, such as a doped region 405, source/drain regions, 410, 415, gate structure 420, and shallow trench isolation regions 425.

FIG. 5 presents the partially-completed integrated circuit 400 after depositing an insulating layer 130 over the semiconductor substrate 115. The insulating layer 130 can comprise any conventional materials including organo-silicate glass, silicon nitride, silicon oxide or multilayered combinations thereof. One skilled in the art would be familiar with conventional methods for forming the insulating layer 130, such as chemical vapor deposition (CVD) or spin-on methodologies.

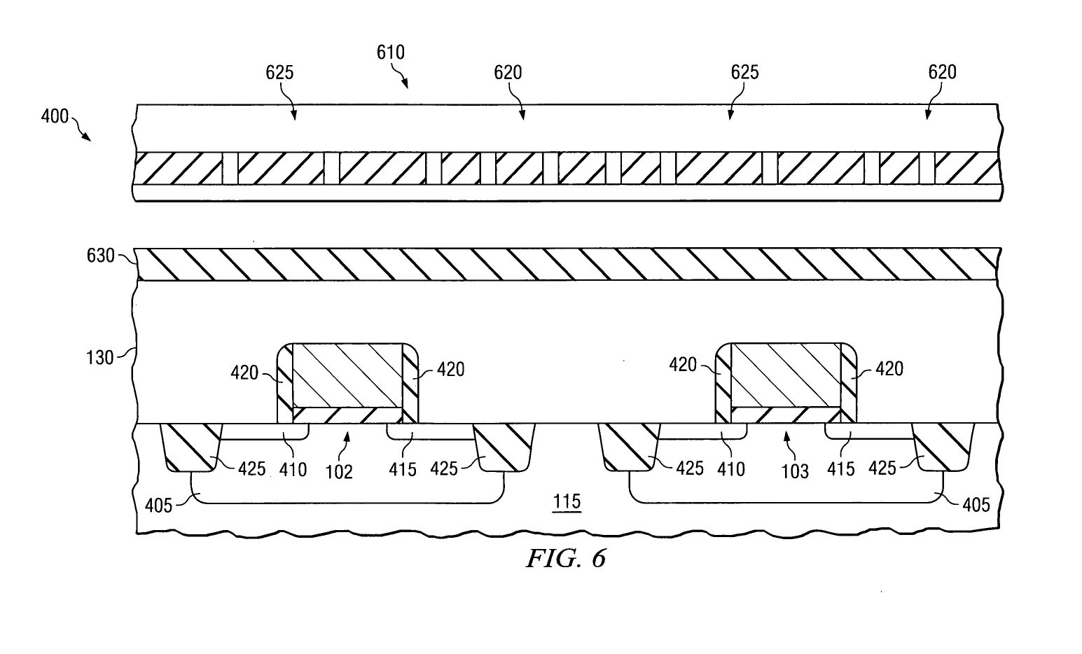

FIGS. 6-8 present different stages of forming interconnects 140 and dummy-fill-structures 150 in the layer 130. As illustrated in FIG. 6, a reticle 610 having a pre-defined recognition pattern 620 of dummy-fill-structures formed therein is positioned over a resist 630 (e.g., conventional photoresist) located on the substrate 115. It is preferable for the reticle 610 to also include an interconnect layout pattern 625 for the layer 130. The resist 630 can comprise a layer formed using conventional techniques, such as spin coating a conventional photoresist material over the substrate 115. The resist can comprise any energy sensitive material that can be patterned upon exposure to radiation (e.g., UV or visible light).

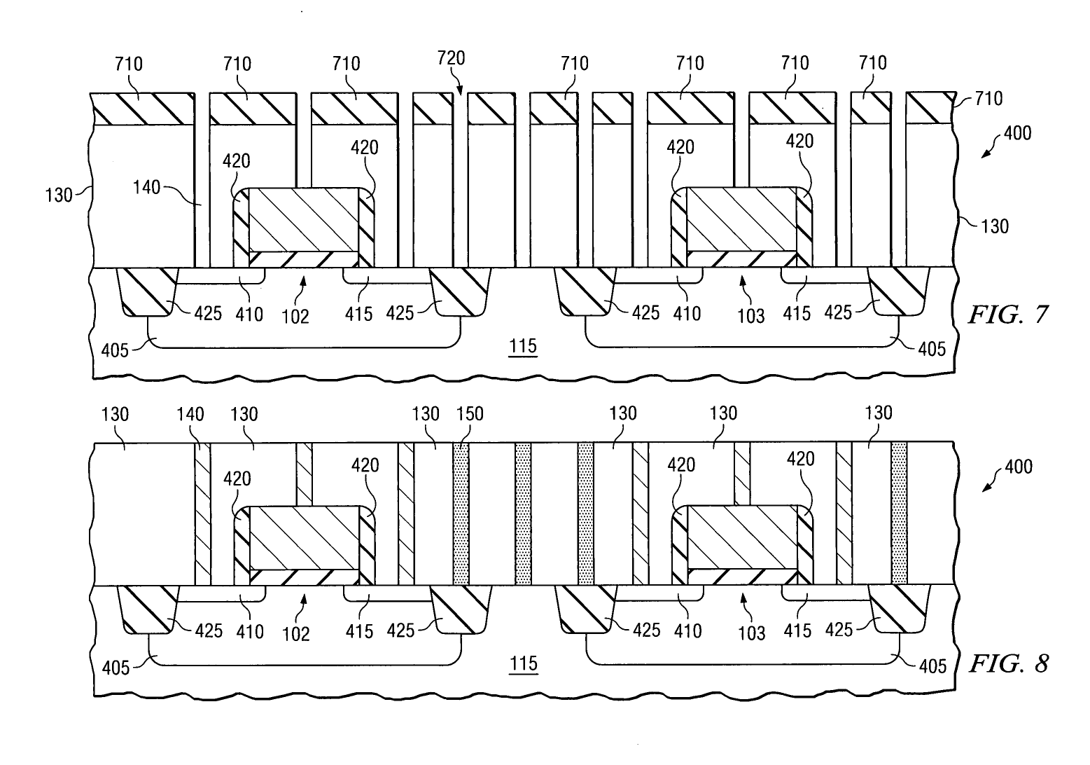

FIG. 7 shows the partially-completed circuit 400 after the resist 630 is exposed, by e.g., shining radiation through the reticle 610 onto the resist 630 (FIG. 6), to transfer the pre-defined recognition pattern into the resist 630 to thereby form a mask 710. FIG. 7 also shows the partially-completed circuit 400 after forming openings 720 in the insulation layer 130 by e.g., etching away portions of the layer 130 not covered, and hence protected, by the mask 720. The openings 720 form the pre-defined recognition pattern in the layer 130.

FIG. 8 illustrates the partially-completed circuit 400 after removing the mask 710 and filling the openings 720 (FIG. 7) with a metal to form the interconnects 140 and dummy-fill-structures 150 in the layer 130. Filling can be accomplished using convention techniques such and CVD, physical vapor deposition, electrochemical deposition or combinations thereof to deposit a metal layer over the layer 130. Preferably, any excess metal outside of the openings 720 is removed by CMP of the layer 130.

In some cases, the interconnects 140 and dummy-fill-structures 150 both comprise tungsten, titanium or combinations thereof. In other cases, the interconnects 140 and dummy-fill-structures 150 both comprise copper. Preferably, copper-containing interconnects 140 and dummy-fill-structures 150 also comprise a barrier material of e.g., tantalum nitride or silicon carbide, to prevent the diffusion of copper atoms out of these structures.

As further illustrated in FIG. 8, the dummy-fill-structures 150 are located between the interconnects 140. Analogous to that discussed above in the context of FIGS. 1-3 the dummy-fill-structures 150 form a plurality of fiducials, each of the fiducials being located in a different region of the layer 130, and each fiducial comprising a pre-defined recognition pattern that is different from every other fiducial in adjacent regions of the layer 130, and in some cases, different from every other fiducial in the layer 130.

FIG. 9 shows the integrated circuit 400 after forming additional layers 132, 110, 134 over the substrate 115. The additional layers 132, 110, 134, interconnects 142, 105, 144 and dummy-fill-structures 152, 120, 154 can be formed in a fashion analogous to that described above in the context of FIGS. 5-8 to couple the semiconductive devices 102, 103 together to form an operative integrated circuit 400.

Those skilled in the art to which the invention relates will appreciate that other and further additions, deletions, substitutions and modifications may be made to the described example embodiments, without departing from the invention.

1. An integrated circuit comprising:
interconnects located in a layer on a semiconductor substrate; and
dummy-fill-structures located between said interconnects in said layer and forming a plurality of fiducials, each of said fiducials being located in a different region of said layer, wherein each fiducial comprises a pre-defined recognition pattern that is different from every other fiducial in adjacent regions of said layer.

2. The circuit of claim 1, wherein said pre-defined recognition pattern for each of said fiducials is different from every other fiducial in said layer.

3. The circuit of claim 1, further comprising additional layers, each of said additional layers comprising said interconnects and said dummy-fill-structures located between said interconnects, wherein said dummy-fill-structures form a plurality of additional fiducials, each of said additional fiducials being located in additional different regions of said additional layers, and wherein said pre-defined recognition pattern for each of said fiducials is different from every other said additional fiducial in said additional regions of vertically adjacent said additional layers.

4. The circuit of claim 3, wherein said pre-defined recognition pattern for each of said fiducials is different from every other said additional fiducial in every other said additional layer.

5. The circuit of claim 1, wherein said pre-defined recognition pattern comprises an ordered arrangement of one or more of said-dummy-fill-structures.

6. The circuit of claim 5, wherein said ordered arrangement comprises a column of said dummy-fill-structures, wherein one or more of said dummy-fill-structures is offset from at least another one of said dummy-fill-structures of said fiducial.

7. The circuit of claim 5, wherein one or more of said dummy-fill-structures is absent from said ordered arrangement.

8. The circuit of claim 7, wherein locations of said absent dummy-fill-structures within said fiducial are selected randomly.

9. The circuit of claim 1, wherein said pre-defined recognition pattern comprises selective ones of said dummy-fill-structures that are electrically grounded.

10. The circuit of claim 1, wherein said pre-defined recognition pattern is substantially repeated in adjacent additional layers.

11. The circuit of claim 10, wherein a location of said dummy-fill-structures is substantially repeated in adjacent additional layers thereby forming an inter-layer vertical column of dummy-fill-structure.

12. The circuit of claim 1, wherein said pre-defined recognition pattern comprises one or more of said dummy-fill-structures, said dummy-fill-structure's morphology configured to make said fiducial different than said every other fiducial in said adjacent regions of said layer.

13. A method of manufacturing an integrated circuit, comprising:
depositing an insulating layer over a semiconductor substrate; and
forming interconnects and dummy-fill-structures in said layer, wherein said dummy-fill-structures are located between said interconnects and form a plurality of fiducials, each of said fiducials being located in a different region of said layer, and each fiducial comprises a pre-defined recognition pattern that is different from every other fiducial in adjacent regions of said layer.

14. The method of claim 13, wherein said pre-defined recognition pattern for each of said fiducials is different from every other fiducial in said layer.

15. The method of claim 13, further comprising forming additional insulating layers over said substrate, each of said additional insulating layers comprising said interconnects and said dummy-fill-structures located between said interconnects, wherein said dummy-fill-structures form a plurality of additional fiducials, each of said additional fiducials being located in additional different regions of said additional layers, and wherein said pre-defined recognition pattern for each of said fiducials is different from every other said additional fiducial in said additional regions of vertically adjacent said additional insulating layers.

16. The method of claim 13, wherein said pre-defined recognition pattern is substantially repeated in adjacent additional layers.

17. The method of claim 13, wherein said pre-defined recognition pattern comprises an ordered arrangement of one or more of said dummy-fill-structures.

18. The method of claim 13, wherein forming said interconnects and said dummy-fill-structures comprises positioning a reticle having said pre-defined recognition pattern formed therein over a resist located on said substrate and exposing said resist to form a mask having said pre-defined recognition pattern.

19. The method of claim 18, wherein forming said interconnects and said dummy-fill-structures comprises removing portions of said layer that are not covered by said mask to form openings in said layer, said openings forming said pre-defined recognition pattern.

20. The method of claim 13, wherein forming said interconnects and said dummy-fill-structures comprise chemical mechanical polishing a metal deposited over said layer.
